(19) United States
(12) Patent Application Publication
(10) Pub. No.: US 2026/0132002 A1
(43) Pub. Date: May 14, 2026

(54) GUIDE FRAME AND GANTRY CRANE

(71) Applicant: Wiwynn Corporation, New Taipei City (TW)

(72) Inventors: Hsien-Chieh HSIEH, New Taipei City (TW); Fu Sheng Cheng, New Taipei City (TW)

(21) Appl. No.: 19/238,631

(22) Filed: Jun. 16, 2025

Related U.S. Application Data
(60) Provisional application No. 63/717,960, filed on Nov. 8, 2024.

(30) Foreign Application Priority Data
May 14, 2025 (TW) 114204827

(51) Int. Cl. B66C 13/06; B66C 17/26

(52) U.S. Cl. CPC B66C 13/06; B66C 17/26

(57) ABSTRACT

A guide frame used for a gantry crane includes a casing, at least one first rolling component and at least one second rolling component. The casing is sleeved on a hanging arm of the gantry crane. The first rolling component is disposed at an inner side of a first side wall of the casing. The second rolling component is disposed at an inner side of a second side wall of the casing located opposite to the first side wall. The first rolling component and the second rolling component are configured to guide an object gripped by the hanging arm to move along a direction of gravity or a direction opposite thereto.

### CROSS-REFERENCE TO RELATED APPLICATIONS

### This non-provisional application claims priority under 35 U.S.C § 119(a) on Provisional Application No(s) 63/717,960 filed in U.S.A. on November 8th, 2024, and Patent Application No(s). 114204827 filed in Taiwan, R.O.C on May 14th, 2025, the entire contents of which are hereby incorporated by reference.

### TECHNICAL FIELD

The disclosure provides a guide frame and a gantry crane.

### BACKGROUND

With the advancement and development of technology, servers are currently cooled by immersing them in a coolant contained in a tank. During the process of moving the server inside or outside of the tank, a gantry crane is used for lifting the server. However, during the lifting process by the gantry crane, the server tends to sway, which may cause damage to the server. In view of this, how to solve the aforementioned issue is one of the topics in this field.

### SUMMARY

As a result, the disclosure is to provide a guide frame and a gantry crane capable of preventing the server from swaying during the lifting process by the gantry crane.

The disclosure provides a guide frame used for a gantry crane. The guide frame includes a casing, at least one first rolling component and at least one second rolling component. The casing is sleeved on a hanging arm of the gantry crane. The first rolling component is disposed at an inner side of a first side wall of the casing. The second rolling component is disposed at an inner side of a second side wall of the casing located opposite to the first side wall. The first rolling component and the second rolling component are configured to guide an object gripped by the hanging arm to move along a direction of gravity or a direction opposite thereto.

The disclosure further provides a gantry crane configured to hang an object. The gantry crane includes a hanging arm, a container and the aforementioned guide frame. The container is configured to contain the object. The guide frame is sleeved on the hanging arm. When the hanging arm grips the object to place the object inside or remove the object outside of the container, the guide frame guides the object along a direction of gravity or a direction opposite thereto.

The guide frame and the gantry crane of the disclosure at least have the following advantage: (1) By having the casing of the guide frame sleeved onto the hanging arm of the gantry crane, the hanging arm can be prevented from swaying the object during hanging, thereby ensuring the proper functionality of the object; (2) With the arrangement of the balancers, the object can be stabilized during the gripping process by the grippers, further preventing the object from swaying; and (3) The larger portion of the gourd-shaped fastening hole provides a wider gripping tolerance, which improves the gripping success rate, while the smaller portion of the gourd-shaped fastening hole limits the movement range of the object, thereby reducing swaying and enhancing stability.

### BRIEF DESCRIPTION OF THE DRAWINGS

The present disclosure will become better understood from the detailed description given herein below and the accompanying drawings which are given by way of illustration only and thus are not intending to limit the present disclosure and wherein:

FIG. 1 is a perspective view of a gantry crane according to one embodiment of the disclosure;

FIG. 2 is a partial exploded view of a gantry crane according to one embodiment of the disclosure;

FIG. 3 is a partially enlarged perspective view of a gantry crane according to one embodiment of the disclosure; and

FIGS. 4 to 7 show an operation process of a gantry crane according to one embodiment of the disclosure.

### DETAILED DESCRIPTION

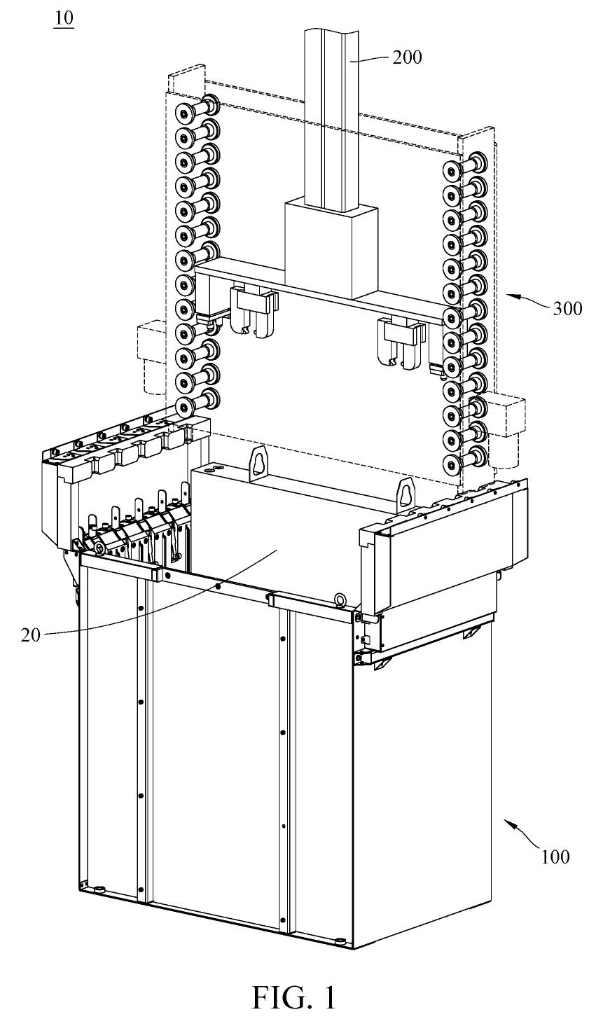

FIG. 1 is a perspective view of a gantry crane 10 according to one embodiment of the disclosure. The gantry crane 10 is configured to hang an object 20 which may be an electronic device, such as a server. The gantry crane 10 includes a container 100, a hanging arm 200, and a guide frame 300. In some embodiments, the container 100 may be an immersion cooling tank. The container 100 is configured to contain the object 20, and the object 20 may be immersed in a coolant (not shown) contained in the container 100. The hanging arm 200 may be connected to a gantry (not shown) and is horizontally movable above the container 100 via the gantry. The hanging arm 200 is configured to grip the object 20 and move vertically to place the object 20 into or remove it from the container 100.

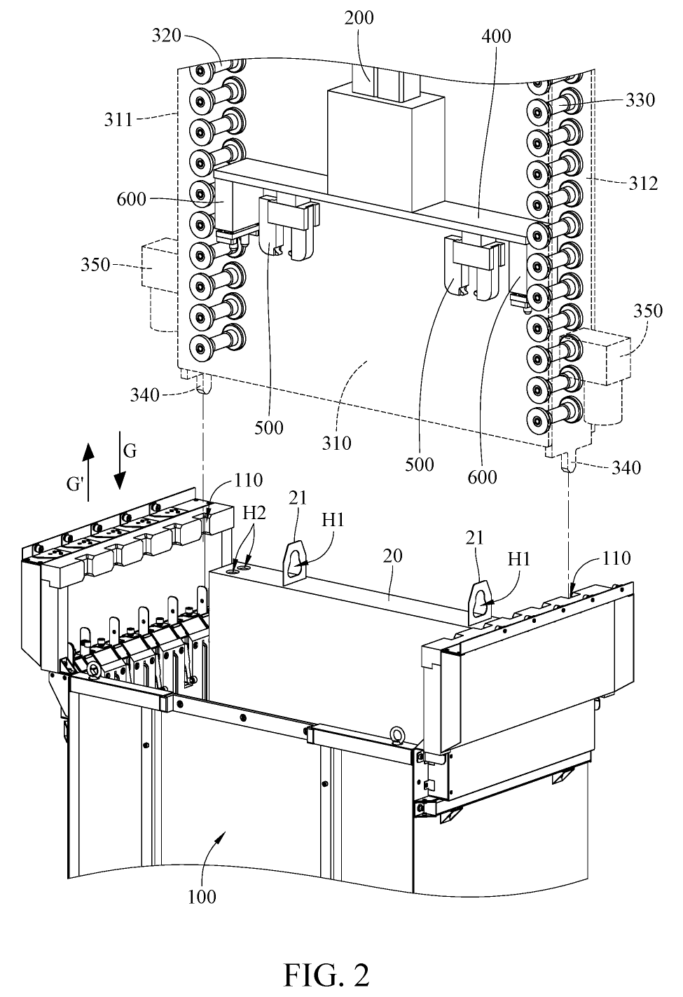

FIG. 2 is a partial exploded view of the gantry crane 10 according to one embodiment of the disclosure. The guide frame 300 includes a casing 310, at least one first rolling component 320, and at least one second rolling component 330. The casing 310 is sleeved on the hanging arm 200. The first rolling component 320 and the second rolling component 330 are respectively disposed on inner sides of a first side wall 311 and a second side wall 312 of the casing 310 located opposite to each other. The first rolling component 320 and the second rolling component 330 are configured to guide the object 20, gripped by the hanging arm 200, to move along a direction of gravity G or a direction G' opposite thereto.

In some embodiments, the first rolling component 320 and the second rolling component 330 may be rollers or universal ball bearings. In some embodiments, the guide frame 300 may include a plurality of first rolling components 320 and a plurality of second rolling components 330. The first rolling components are arranged along the direction of gravity G on the first side wall 311, and the second rolling components are arranged along the direction of gravity G on the second side wall 312.

In some embodiments, the guide frame 300 may include at least one positioning pillar 340, and the container 100 may be formed with at least one positioning hole 110. The positioning pillar 340 is disposed on a bottom of at least one of the first side wall 311 and the second side wall 312. The positioning hole 110 of the container 100 corresponds to the positioning pillar 340. In some embodiments, the guide frame 300 may include two positioning pillars 340, which are respectively disposed on the bottoms of the first side wall 311 and the second side wall 312. Additionally, the container 100 may be formed with two positioning holes 110, which respectively correspond to the two positioning pillars 340.

In some embodiments, the guide frame 300 may include at least one position sensor 350. The position sensor 350 is disposed on an outer side of at least one of the first side wall 311 and the second side wall 312 of the guide frame 300, and is configured to sense the container 100. For example, the position sensor 350 may be an optical sensor, and a pattern (not shown) may be provided on the container 100. By detecting the pattern on the container 100 via the position sensor 350, it can be determined that the guide frame 300 is approximately aligned with the container 100.

In some embodiments, the guide frame 300 may include two position sensors 350, which are respectively disposed on outer sides of the first side wall 311 and the second side wall 312. By detecting two patterns on the container 100 via the two position sensors 350, it can be determined that the guide frame 300 is aligned with the container 100, such that the two positioning pillars 340 can be smoothly inserted into the two positioning holes 110.

In some embodiments, the gantry crane 10 may include a holder 400 and two grippers 500. The holder 400 is connected to the hanging arm 200. The two grippers 500 are respectively disposed on two opposite sides of the holder 400, and are configured to grip the object 20. In certain embodiments, the object 20 includes two hang tabs 21, and each of the two hang tabs 21 is formed with a gourd-shaped fastening hole H1. Specifically, an upper portion of the fastening hole H1 has a smaller inner diameter, and a lower portion has a larger inner diameter. During the lift movement of the object 20, the hanging arm 200 moves the grippers 500 downward to reach the fastening hole H1, the grippers 500 pass through the lower portions of the fastening holes H1 with the larger inner diameters and then close, and then the hanging arm 200 moves the grippers 500 upward. Note that the lower portions of the fastening holes H1 with the larger inner diameters provide a greater tolerance for the grippers 500 to penetrate through the hang tabs 21, thereby increasing the gripping success rate—that is, preventing the grippers 500 from directly clamping the hang tabs 21 or an area outside the hang tab 21. Under the influence of gravity, the object 20 drops slightly so that the grippers 500 abuts against the upper portions of the fastening holes H1 with the smaller inner diameters. This configuration restricts the movement range of the object 20, thereby reducing shaking and enhancing stability. Accordingly, the gourd-shaped fastening holes H1 provide the dual benefits of a high gripping success rate and improved stability.

In some embodiments, the gantry crane 10 may include two balancers 600. The two balancers 600 are respectively disposed on two opposite sides of the holder 400, and are configured to balance the object 20. The two grippers 500 are located between the two balancers 600. Noticeably, during the horizontal movement of the object 20, since the two balancers 600 contact the upper surface of the object 20, the lateral sway of the object 20 can be reduced, thereby improving stability.

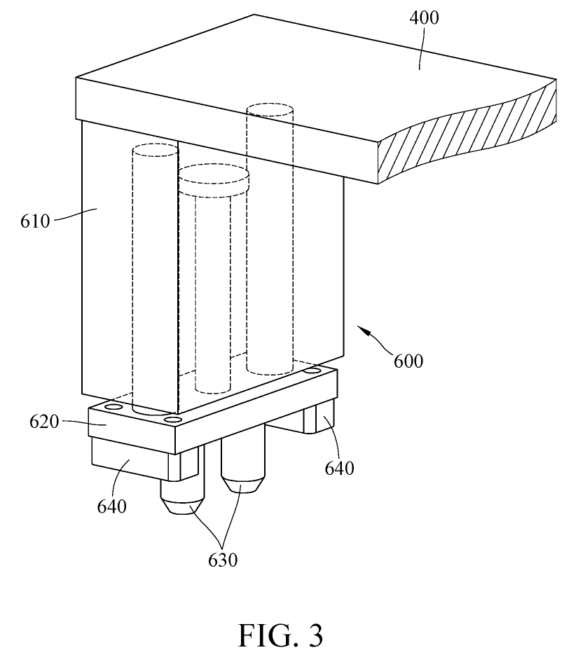

FIG. 3 is a partially enlarged perspective view of the gantry crane 10 according to one embodiment of the disclosure. In some embodiments, each of the balancers 600 may include an actuator 610, a movable component 620, at least one positioning pin 630, and at least one cushion 640. Taking one of the balancers 600 as an example, the actuator 610 is disposed on the holder 400. In some embodiments, the actuator 610 may be an electric actuator or a pneumatic cylinder. The movable component 620 is movably disposed on the actuator 610. Specifically, the actuator 610 includes a piston rod configured to extend and retract, and the movable component 620 is fixed to the piston rod, so that the movable component 620 can move together with the piston rod. The positioning pin 630 is disposed on the movable component 620 and is configured to be inserted into an insertion hole H2 of the object 20 (as shown in FIG. 2). The cushion 640 is disposed on the movable component 620, and is configured to contact the object 20. In some embodiments, the balancer 600 may include two positioning pins 630 and two cushions 640, and the two positioning pins 630 are located between the two cushions 640. During the process of the grippers 500 gripping the object 20, the actuator 610 drives the movable component 620 via the piston rod, thereby moving the positioning pins 630 and the cushions 640 together toward the object 20, until the actuator 610 has completed a predetermined extension stroke. At this moment, the positioning pins 630 are inserted into the insertion holes H2, and the cushions 640 contact the object 20. Note that the positioning pins 630 must be inserted into the insertion holes H2 prior to the gripping process of the grippers 500. Therefore, the positioning pins 630 and the insertion holes H2 assist in aligning the grippers 500 with the hang tabs 21 of the object 20.

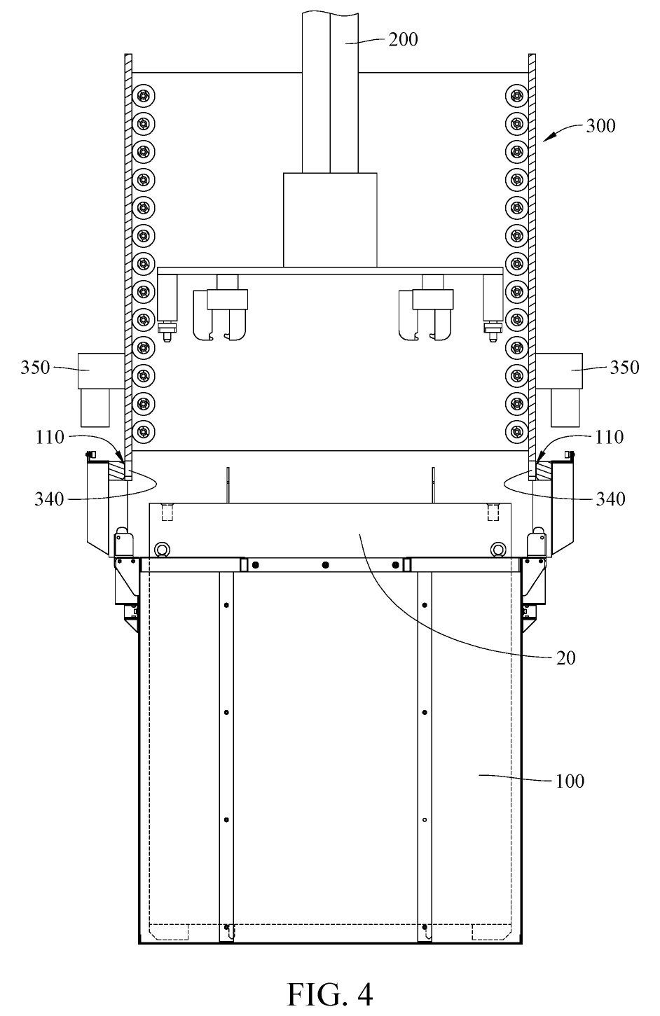

FIGS. 4 to 7 show an operation process of the gantry crane 10 according to one embodiment of the disclosure.

As shown in FIG. 4, when the object 20 is to be removed from the container 100, the gantry first moves the hanging arm 200 along with the guide frame 300 to a position above the container 100. The position sensors 350 sense patterns on the container 100 to determine that the guide frame 300 is approximately aligned with the container 100. Then, the hanging arm 200 and the guide frame 300 descend together, such that the positioning pillars 340 of the guide frame 300 are inserted into the positioning holes 110 of the container 100, thereby positioning the guide frame 300 relative to the container 100.

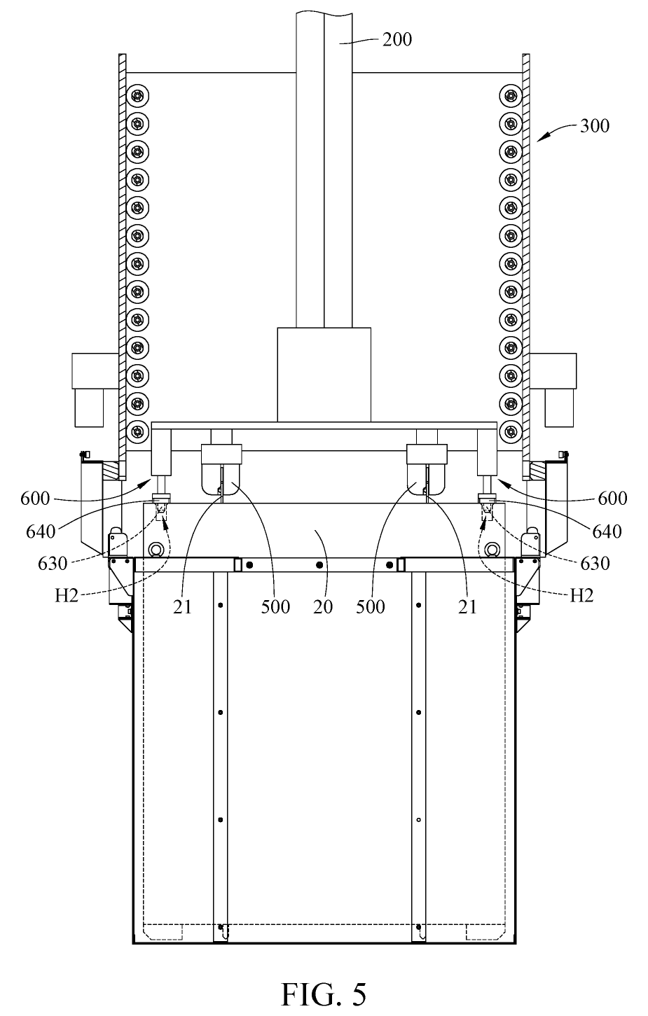

As shown in FIG. 5, the hanging arm 200 descends relative to the guide frame 300, causing the positioning pins 630 of the balancers 600 to be inserted into the insertion holes H2 of the object 20, and the cushions 640 to contact the object 20. Then, the two grippers 500 respectively grip the two hang tabs 21 of the object 20.

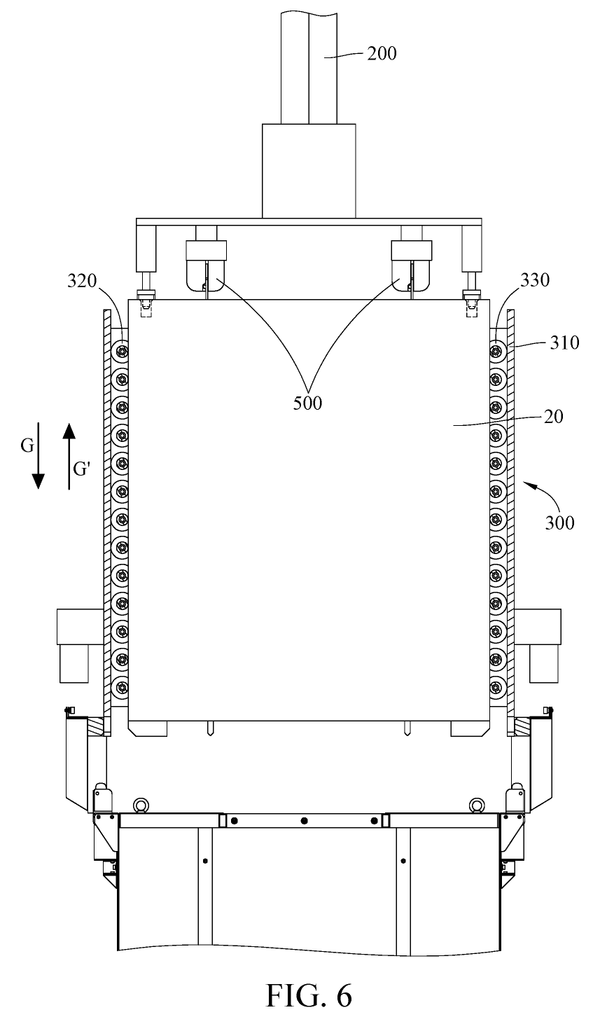

As shown in FIG. 6, the hanging arm 200 ascends relative to the guide frame 300, causing the object 20 gripped by the grippers 500 to enter the casing 310 of the guide frame 300. The first rolling components 320 and the second rolling components 330 guide the object 20 to move along the direction G’ opposite to the direction G of gravity.

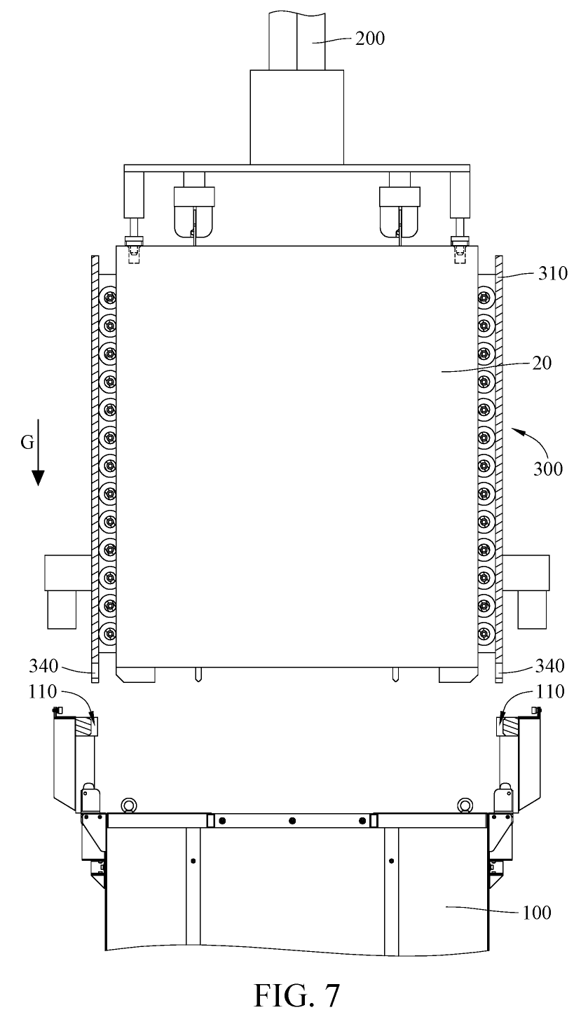

As shown in FIG. 7, after the object 20 has been completely removed from the container 100 and moved into the casing 310, the hanging arm 200 and the guide frame 300 ascend together, allowing the positioning pillars 340 of the guide frame 300 to disengage from the positioning holes 110 of the container 100. At this moment, the hanging arm 200 and the guide frame 300 can move horizontally in a direction perpendicular to the direction G of gravity, so as to transport the object 20 gripped by the grippers 500 to another location (e.g., a cart).

Conversely, when the object 20 is to be placed into the container 100, the above steps may be performed in reverse to complete the placement of the object 20 into the container 100.

In summary, the guide frame and the gantry crane of the disclosure have the following advantage:(1) By having the casing of the guide frame sleeved onto the hanging arm of the gantry crane, the hanging arm can be prevented from swaying the object during hanging, thereby ensuring the proper functionality of the object;(2)With the arrangement of the balancers, the object can be stabilized during the gripping process by the grippers, further preventing the object from swaying; and (3) The larger portion of the gourd-shaped fastening hole provides a wider gripping tolerance, which improves the gripping success rate, while the smaller portion of the gourd-shaped fastening hole limits the movement range of the object, thereby reducing swaying and enhancing stability.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A guide frame used for a gantry crane, and comprising:
a casing sleeved on a hanging arm of the gantry crane;
at least one first rolling component, disposed at an inner side of a first side wall of the casing; and
at least one second rolling component, disposed at an inner side of a second side wall of the casing located opposite to the first side wall;
wherein the at least one first rolling component and the at least one second rolling component are configured to guide an object gripped by the hanging arm to move along a direction of gravity or a direction opposite thereto.

2. The guide frame according to claim 1, wherein the at least one first rolling component and the at least one second rolling component are rollers or universal ball bearings.

3. The guide frame according to claim 1, further comprising:
at least one positioning pillar disposed on a bottom of at least one of the first side wall and the second side wall, and configured to position the guide frame to a container containing the object;
wherein the container is formed with at least one positioning hole corresponding to the at least one positioning pillar.

4. The guide frame according to claim 1, wherein the gantry crane comprises:
a holder connected to the hanging arm; and
two grippers respectively disposed on two opposite sides of the holder, and configured to grip the object.

5. The guide frame according to claim 4, wherein the object comprises:
two hang tabs respectively formed with a gourd-shaped fastening hole, and configured to be gripped by the two grippers.

6. The guide frame according to claim 4, wherein the gantry crane further comprises:
two balancers respectively disposed on two opposite sides of the holder, and configured to balance the object, wherein the two grippers are located between the two balancers.

7. The guide frame according to claim 6, wherein each of the two balancers comprises:
an actuator disposed on the holder;
a movable component movably disposed on the actuator;
at least one positioning pin disposed on the movable component, and configured to be inserted into the object; and
at least one cushion disposed on the movable component, and configured to contact the object.

8. The guide frame according to claim 1, further comprising:
at least one position sensor disposed at an outer side of at least one of the first side wall and the second side wall, and configured to sense a container containing the object.

9. The guide frame according to claim 1, wherein the object is a server, and a container containing the object is an immersion cooling tank.

10. A gantry crane configured to hang an object, and comprising:
a hanging arm;
a container configured to contain the object; and
the guide frame according to claim 1, and sleeved on the hanging arm;
wherein, when the hanging arm grips the object to place the object inside or remove the object outside of the container, the guide frame guides the object along a direction of gravity or a direction opposite thereto.
